(19) United States
(12) Patent Application Publication
(10) Pub. No.: US 2010/0078315 A1
(43) Pub. Date: Apr. 1, 2010

(54) MICROSTRIP ANTENNA ASSISTED IPVD

(75) Inventor: Michael W. Stowell, Loveland, CO (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/238,685

(22) Filed: Sep. 26, 2008

(51) Int. Cl. C23C 14/34

(52) U.S. Cl. 204/192.22; 204/298.02; 204/298.13; 204/298.12; 204/298.08; 204/192.12; 204/192.25; 204/192.15

(57) ABSTRACT

The invention provides a microwave source to assist in sputtering deposition. Such a microwave source comprises a microstrip antenna that is attached to an end of a dielectric layer outside a sputtering target or cathode. The microstrip antenna comprising a dielectric coated metal strip radiates microwave between the sputtering cathode and a cathode dark space that is formed near the sputtering cathode. The microwave enhances plasma density in the cathode dark space. With the assistance of the microwave source, the sputtering target is able to operate at a lower pressure, a lower voltage and may yield higher deposition rates than without the microwave source. The target may have a generally circular or rectangular cross section. The microstrip may be of a curved strip such as a ring shape or a straight strip, depending upon the shape of the sputtering target.

### BACKGROUND OF THE INVENTION

Glow discharge thin film deposition processes are extensively used for industrial applications and materials research, especially in creating new advanced materials. Although chemical vapor deposition (CVD) generally exhibits superior performance for deposition of materials in trenches or holes, physical vapor deposition (PVD) is sometimes preferred because of its simplicity and lower cost. In PVD, magnetron sputtering is often preferred, as it may have approximately 100 times increase in deposition rate and about 100 times lower required discharge pressure than non-magnetron sputtering. Inert gases, especially argon, are usually used as sputtering agents because they do not react with target materials. When a negative voltage is applied to a target, positive ions, such as positively charged argon ions, hit the target and knock the atoms out. Secondary electrons are also ejected from the target surface. A magnetic field can trap the secondary electrons close to the target and the secondary electrons can result in more ionizing collisions with inert gases. This enhances the ionization of the plasma near the target and leads to a higher sputtering rate. It also means that the plasma can be sustained at a lower pressure. In conventional magnetron sputtering, a higher deposition rate may be achieved by increasing the power to the target or decreasing the distance from the target. However, one drawback is that magnetized plasma tends to have larger variations in plasma density, because the strength of the magnetic field significantly varies with distance. This non-homogeneity may cause complications for deposition of large areas. Also, conventional magnetron sputtering has relatively low deposition rate.

Unlike evaporative techniques, the energy of ions or atoms in PVD is comparable to the binding energy of typical surfaces. This would in turn help increase atom mobility and surface chemical reaction rates so that epitaxial growth may occur at reduced temperatures and synthesis of chemically metastable materials may be allowed. By using energetic atoms or ions, compound formation may also become easier. An even greater advantage can be achieved if the deposition material is ionized. In this case, the ions can be accelerated to desired energies and guided in direction by using electric or magnetic fields to control film intermixing, nano- or microscale modification of microstructure, and creation of metastable phases. Because of the interest in achieving a deposition flux in the form of ions rather than neutrals, several new ionized physical vapor deposition (IPVD) techniques have been developed to ionize the sputtered material and subsequently direct the ions toward the substrate using a plasma sheath that is generated by using an RF bias on the substrate.

The ionization of atoms requires a high density plasma, which makes it difficult for the deposition atoms to escape without being ionized by energetic electrons. Capacitively generated plasmas are usually very lightly ionized, resulting in low deposition rate. Denser plasma may be created using inductive discharges. Inductively coupled plasma may have a plasma density of 10¹¹ ions/cm³, approximately 100 times higher than comparable capacitively generated plasma. A typical inductive ionization PVD uses an inductively coupled plasma that is generated by using an internal coil with a 13.56-MHz RF source. A drawback with this technique is that ions with about 100 eV in energy bombard the coil, erode the coils and then generate sputtered contaminants that may adversely affect the deposition. Also, the high energy of the ions may cause damage to the substrate. Some improvement has been made by using an external coil to resolve the problem associated with the internal ICP coil.

Another technique for increasing plasma density is to use a microwave frequency source. It is well known that at low frequencies, electromagnetic waves do not propagate in a plasma, but are instead reflected. However, at high frequencies such as typical microwave frequency, electromagnetic waves effectively allow direct heating of plasma electrons. As the microwaves input energy into the plasma, collisions can occur to ionize the plasma so that higher plasma density can be achieved. Typically, horns are used to inject the microwaves or a small stub antenna is placed in the vacuum chamber adjacent to the sputtering cathode for inputting the microwaves into the chamber. However, this technique does not provide a homogeneous assist to enhance plasma generation. It also does not provide enough plasma density to sustain its own discharge without the assistance of the sputtering cathode. Additionally, scale up of such systems for large area deposition is limited to a length on the order of 1 meter or less due to non-linearity.

There remains a need for providing a high density homogeneous discharge adjacent to a sputtering cathode to increase localized ionization efficiency and to deposit films over large areas. There still remains a need for providing a microwave source adjacent to the sputtering cathode at reasonably lower cost. There is also a need for lowering the energy of the ions to reduce surface damage to the substrate and thus reduce defect densities. There is a further need to affect the microstructure growth and deposition coverage such as gapfill in narrow trenches and to enhance film chemistry through controlling ion density and ion energy in the bulk plasma and near the substrate surface.

### BRIEF SUMMARY OF THE INVENTION

Embodiments of the invention provide a microwave source to assist in sputtering deposition. Such a microwave source comprises a microstrip antenna that is attached to an end of a dielectric layer outside a sputtering target or cathode. The microstrip antenna comprising a dielectric coated metal strip radiates microwave between the sputtering cathode and a cathode dark space that is formed near the sputtering cathode. The microwave enhances plasma density in the cathode dark space. With the assistance of the microwave source, the sputtering target is able to operate at a lower pressure, a lower voltage and may yield higher deposition rates than without the microwave source. The target may have a generally circular or rectangular cross section. The microstrip may be of a curved strip such as a ring shape or a straight strip, depending upon the shape of the sputtering target.

In one set of embodiments of the invention, the sputtering target is of a circular shape. The microstrip antenna comprises a ring strip attached to a top of a dielectric layer outside the sputtering target and a conductive layer attached to a bottom of the dielectric layer for grounding. The micro strip antenna radiates microwaves into the cathode dark space. In a special embodiment of the invention, the sputtering target comprising a dielectric material, a metal or a semiconductor. A power source is adapted to the sputtering target for providing a DC power if the sputtering target comprises a metal, or an AC power, an RF power or a pulsed power if the sputtering target comprises dielectric material or semiconductor.

In another set of embodiments of the invention, the sputtering target is of a rectangular shape. The microstrip antenna comprises a straight strip that is attached to a top of a dielectric layer outside the sputtering target and a conductive layer that is attached to a bottom of the dielectric layer outside the sputtering target for grounding. The embodiments of the invention further include a power source adapted to the sputtering target for providing a DC power, an AC power, or a pulsed power.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings.

### BRIEF DESCRIPTION OF THE DRAWINGS

FIG. 1 is an exemplary simplified microwave-assisted sputtering system.

FIG. 2A is a top view of an exemplary microstrip antenna attached to a dielectric substrate outside a generally circular sputtering target.

FIG. 2B is a side view of an exemplary microstrip antenna attached to a dielectric substrate outside a generally circular sputtering target.

FIG. 3A is a top view of an exemplary microstrip antenna attached to a dielectric substrate outside a generally rectangular sputtering target.

FIG. 3B is a side view of an exemplary microstrip antenna attached to a dielectric substrate outside a generally rectangular sputtering target.

FIG. 4 is a flow chart for illustrating simplified deposition steps for forming a film on a substrate.

FIG. 5 illustrates the effect of pulsing frequency on the light signal from plasma.

FIG. 6 is a graph demonstrating the saturation of continuous microwave plasma density versus microwave power.

FIG. 7 is a graph showing the improved plasma efficiency in using pulsed microwave power when compared to continuous microwave power.

### DETAILED DESCRIPTION OF THE INVENTION

### 1. Overview of Microwave Assisted Deposition and Microstrip Antenna

Microwave plasma has been developed to achieve higher plasma densities (e.g. ˜10¹² ions/cm³) and higher deposition rates, as a result of improved power coupling and absorption at higher microwave frequency ranging from 1 GHz to 10 GHz, when compared to a typical radio frequency (RF) coupled plasma sources at 13.56 MHz, for example, commonly 2.45 GHz. In addition, a higher frequency of 5.8 GHz is often used when power requirement is not as critical. The benefit of using a higher frequency source is that it has smaller size (about half size) of the lower frequency source of 2.45 GHz. One drawback of the RF plasma is that a large portion of the input power is dropped across a plasma sheath (dark space). By using microwave plasma, a narrow plasma sheath is formed and more power can be absorbed by the plasma for creation of radical and ion species, which increases the plasma density and reduces collision broadening of the ion energy distribution to achieve a narrow energy distribution.

Microwave plasma also has other advantages such as lower ion energies with a narrow energy distribution. For instance, microwave plasma may have low ion energy of 1-25 eV, which leads to lower damage when compared to RF plasma. In contrast, standard planar discharge would result in high ion energy of 100 eV with a broader distribution in ion energy, which would lead to higher damage, as the ion energy exceeds the binding energy for most materials of interest. This ultimately inhibits the formation of high quality crystalline thin films through introduction of intrinsic defects. With low ion energy and narrow energy distribution, microwave plasma helps in surface modification and improves coating properties.

In addition, a lower substrate temperature (e.g. lower than 200° C., for instance at 100° C.) is achieved, as a result of increased plasma density at lower ion energy with narrow energy distribution. Such a lower temperature allows better microcrystalline growth in kinetically limited conditions. Also, standard planar discharge without magnetron normally requires pressure greater than about 50 mtorr to maintain self-sustained discharge, as plasma becomes unstable at pressure lower than about 50 mtorr. The microwave plasma technology described herein allows the pressure to range from about 10⁻⁶ torr to 1 atmospheric pressure. The processing windows such as temperature and pressure are therefore extended by using a microwave source.

In the past, one drawback associated with microwave source technology in the vacuum coating industry was the difficulty in maintaining homogeneity during the scale up from small wafer processing to very large area processing. Microwave reactor designs in accordance with embodiments of the invention address these problems. Arrays of coaxial plasma linear sources have been developed to deposit substantially uniform coatings of ultra large area (greater than 1 m²) at high deposition rate to form dense and thick films (e.g. 5-25 μm thick).

An advanced pulsing technique has been developed to control the microwave power for generating plasma, and thus to control the plasma density and plasma temperature. This advanced pulsing technique may reduce the thermal load disposed over the substrate, as the average power may remain low. This feature is relevant when the substrate has a low melting point or a low glass transition temperature, such as in the case of a polymer substrate. The advanced pulsing technique allows high power pulsing into plasma with off times in between pulses, which reduces the need for continuous heating of the substrate. Another aspect of the pulsing technique is significant improvement in plasma efficiency compared to continuous microwave power.

Microstrip is a type of electrical transmission line which can be fabricated using printing circuit board (PCB) technology and is used to convey microwave-frequency signals. It consists of a conducting strip separated from a ground plane by a dielectric layer or a substrate. Microwave antennas can be formed from microstrips comprising metals. Microstrip is thus much cheaper than traditional waveguide technology, such as coaxial microwave line sources that are described in several related patent applications: U.S. patent application Ser. No. ______, entitled “Coaxial Microwave Assisted Deposition and Etch System,” filed by Michael W. Stowell, Net Krishna, Ralf Hofman, and Joe Griffith (Attorney Docket No. A12659/T83600); U.S. patent application Ser. No. ______, entitled “Microwave Rotatable Sputtering Deposition,” filed by Michael W. Stowell, Net Krishna (Attorney Docket No. A012144/T82800); U.S. patent application Ser. No. ______, entitled “Microwave-Assisted Rotatable PVD,” filed by Michael W. Stowell, Net Krishna (Attorney Docket No. A012151/T86000); and U.S. patent application Ser. No. ______, entitled “Microwave Plasma Containment Shielding,” filed by Michael W. Stowell (Attorney Docket No. A011869/T082600). The entire contents of each of the foregoing patent applications are incorporated herein by reference for all purposes.

Plasmas that are excited by propagation of electromagnetic surface waves are called surface wave-sustained plasmas. The surface wave may allow to generate uniform plasma in volumes that have lateral dimensions extending to a few wavelengths of the electromagnetic waves, for example, a microwave of 2.45 GHz in vacuum, the wavelength is about 12.2 cm. However, electromagnetic waves cannot propagate in over-dense plasmas, such as a plasma density of 10¹² ions/cm³ or higher. The electromagnetic waves are reflected at the plasma surface because of a skin effect. The skin or penetration depth 6 may be in an order of a few microns. Instead of electromagnetic waves traversing the plasma, the conductivity of the plasma enables the electromagnetic waves to propagate along the plasma surface. The electromagnetic wave energy is then transferred to the plasma by an evanescent wave that enters the plasma perpendicularly to the surface of the plasma and decays exponentially with the skin depth. Hence, the plasma is heated so that plasma density is increased.

This invention is an extension of the microstrip application to thin film processing by using a microstrip antenna to radiate surface microwaves between a sputtering target and a cathode plasma sheath or dark space which is further explained below. The microwaves generated from the microstrip antenna near the sputtering target may help enhance plasma density. The microstrip antenna may have lower power and higher losses than the coaxial microwave line source. Surface wave-sustained plasmas may be operated in various geometries. The pressure range depends upon the chamber size. The larger the chamber size, the lower the minimum pressure required for the surface wave-sustained plasmas.

The electromagnetic waves carried by a microstrip exist partially in a dielectric substrate and partially in the air above it or a vacuum chamber. The microstrip does not support a true transverse electromagnetic (TEM) wave, which means that the electric and magnetic fields are both perpendicular to the direction of propagation. Instead, the microstrip supports a quasi-TEM wave, i.e. both the E and M fields have longitudinal components. This is different from the coaxial microwave line source, where the coaxial line behaves as a waveguide above a cutoff frequency. The electromagnetic waves generated from the coaxial lines are in a TEM mode, which means that the electromagnetic waves or microwaves above the cutoff frequency have no longitudinal components.

### 2. Sputtering Cathode and Conditions for Sustaining Plasma Discharge

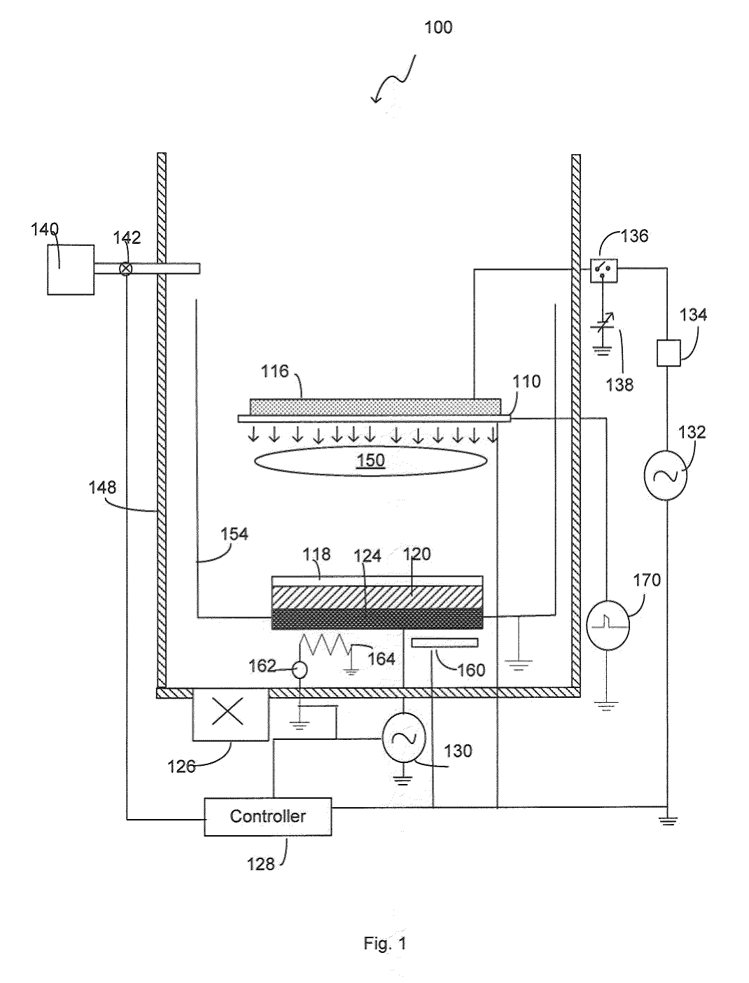

Referring to FIG. 1, target 116 in sputtering system 100 may be made of metal, dielectric material, or semiconductor. For a metal target such as aluminum, copper, titanium, or tantalum, a DC voltage may be applied to the target to make the target a cathode and the substrate an anode. The DC voltage would help accelerate free electrons. The free electrons collide with sputtering agents such as argon (Ar) atoms from argon gas to cause excitation and ionization of Ar atoms. The excitation of Ar results in gas glow. The ionization of Ar generates Ar⁺ and secondary electrons. The secondary electrons repeat the excitation and ionization process to sustain the plasma discharge.

Near the cathode, positive charges build up as the electrons move much faster than ions due to their smaller mass. Therefore, fewer electrons collide with Ar so that fewer collisions with the high energy electrons result in mostly ionization rather than excitation. A cathode dark space that is also called Crookes dark space is formed near the cathode. Positive ions entering the cathode dark space are accelerated toward the cathode or target and bombard the target so that atoms are knocked out from the target and then transported to the substrate and also secondary electrons are generated to sustain the plasma discharge. If the distance between cathode to anode is less than the dark space, few excitations occur and discharge can not be sustained. On the other hand, if the Ar pressure in a chamber is too low, there would be a larger electron mean free path such that secondary electrons would reach anode before colliding with Ar atoms. In this case, discharge also can not be sustained. Therefore, a condition for sustaining the plasma is

L*P>0.5 (cm-torr)

where L is the electrode spacing and P is the chamber pressure. For instance, if a spacing between the target and the substrate is 10 cm, P should be greater than 50 mtorr.

The mean free path λ of an atom in a gas is given by:

λ(cm)˜5×10⁻³/P (torr)

If P is 50 mtorr, λ is about 0.1 cm. This means that sputtered atoms or ions typically have hundreds of collisions before reaching the substrate. This reduces the deposition rate significantly. In fact, the sputtering rate R is inversely proportional to the chamber pressure and the spacing between target and substrate. Therefore, lowering required chamber pressure for sustaining discharge increases deposition rate.

With a secondary microwave source near the sputtering cathode, the sputtering system allows the cathode to run at a lower pressure, lower voltage and possibly higher deposition rate. By decreasing operational voltage, atoms or ions have lower energy so that damage to the substrate is reduced. With the high plasma density and lower energy plasma from microwave assist, high deposition rate can be achieved along with lower damage to the substrate.

Referring to FIG. 1 again, the target 116 in the sputtering system 100 may be made of dielectric material, such as silicon oxide, aluminum oxide, or titanium oxide. The target 106 may be subjected to AC, RF, or pulsing power to accelerate free electrons.

### 3. Exemplary Microstrip Antenna Assisted IPVD

FIG. 1 depicts a simplified schematic, cross-sectional diagram of a physical vapor deposition (PVD) system 100 assisted with a microstrip microwave antenna 110. The system may be used to practice embodiments of the invention. The system 100 includes a vacuum chamber 148, a target 116, a microstrip antenna 110 positioned near the target 116, a substrate supporting member 124, a vacuum pump system 126, a controller 128, gas supply system 140, and a shield 154 for protecting the chamber walls and the sides of the substrate supporting member from sputtering deposition. The following references, i.e. U.S. Pat. No. 6,620,296 B2, U.S. Patent Application Pub. No. US 2007/0045103 A1, and U.S. Patent Application Pub. No. US2003/0209422 A1, are cited here for exemplary PVD systems used by Applied Materials and others and are incorporated herein by reference for all purposes.

Target 116 is a material to form plasma 150 and to be deposited on a substrate 120 to form a film 118. The target 116 may comprise dielectric materials or metals. The target is typically structured for removable insertion into the corresponding PVD system 100. Targets 116 are periodically replaced with new targets given that the PVD process erodes away the target material.

Both DC power supply 138 and the high frequency or pulsing power supply 132 are coupled through a device to the target 116. The device may be a switch 136. The switch 136 selects power from either the DC power supply 138 or the power from the AC, RF or pulsing power supply 132. A DC power supply 138 provides a DC cathode voltage of a few hundred volts. The specific cathode voltage varies with design. As the target can act as a source of negatively charged particles, the target may also be referred to as the cathode. Those skilled in the art will realize that there may be many ways for switching DC and RF power that would fulfill the function. Furthermore, in some embodiments, it may be advantageous to have both DC and RF power coupled to the target simultaneously.

The microwaves input energy into the plasma and the plasma is heated to enhance ionization and thus increase plasma density. One of the advantages of the microstrip antenna 110 is to provide a homogeneous discharge adjacent to sputtering cathode or target 116. This allows substantially uniform deposition of a large area over substrate 120. The antenna 110 may be subjected to a pulsing power 170 or continuous power (not shown). The microstrip antenna 110 is simpler and easier to be fabricated than a coaxial microwave line source and thus has lower cost than the coaxial microwave line source.

For the purpose of controlling the deposition of sputtered layer or film 118 on substrate 120, the substrate 120 may be biased by an RF power 130 coupled to the substrate supporting member 124 which is provided centrally below and spaced apart from the target 116, usually within the interior of the shield 154. The bias power may have a typical frequency of 13.56 MHz, or more generally between 400 kHz to about 500 MHz. The supporting member is electrically conductive and is generally coupled to ground or to another relatively positive reference voltage so as to define a further electrical field between the target 116 and the supporting member 124. The substrate 120 may be a wafer, such as a silicon wafer, or a polymer substrate. The substrate 120 may be heated or cooled during sputtering, as a particular application requires. A power supply 162 may provide current to a resistive heater 164 embedded in the substrate supporting member 124, commonly referred to as a pedestal, to thereby heat the substrate 120. A controllable chiller 160 may circulate chilled water or other coolants to a cooling channel formed in the pedestal. It is desirable that the deposition of film 118 be uniform across the entire top surface of the substrate 120.

Vacuum pump 126 can pump the chamber 148 to a very low base pressure in the range of 10⁻⁸ torr. A gas supply system 140 connected to the chamber 148 through a mass flow controller 142 supplies inert gases such as argon (Ar), helium (He), xenon (Xe), and/or combinations thereof. The gases may be flowed into the chamber near the top of the chamber as illustrated in FIG. 1 above target 116, or in the middle of the chamber (not shown) between the substrate 120 and target 116. The pressure of the sputtering gases inside the chamber is typically maintained between 0.2 mtorr and 100 mtorr.

A microprocessor controller 128 controls the position of the microstrip antenna 110, a pulsing power or continuous power supply 170 for microwave, mass flow controller 142, a high frequency power supply 132, a DC power supply 138, a bias power supply 130, a resistive heater 164 and a chiller 160. The controller 128 may include, for example, a memory such as random access memory, read only memory, a hard disk drive, a floppy disk drive, or any other form of digital storage, local or remote, and a card rack coupled to a general purpose computer processor (CPU). The controller operates under the control of a computer program stored on the hard disk or through other computer programs, such as stored on a removable disk. The computer program dictates, for example, the timing, mixture of gases, pulsing or continuous power to the microwave antenna, DC or RF power applied on targets, biased RF power for substrate, substrate temperature, and other parameters of a particular process.

### 4. Exemplary Microstrip Antennas Proximate Sputtering Target

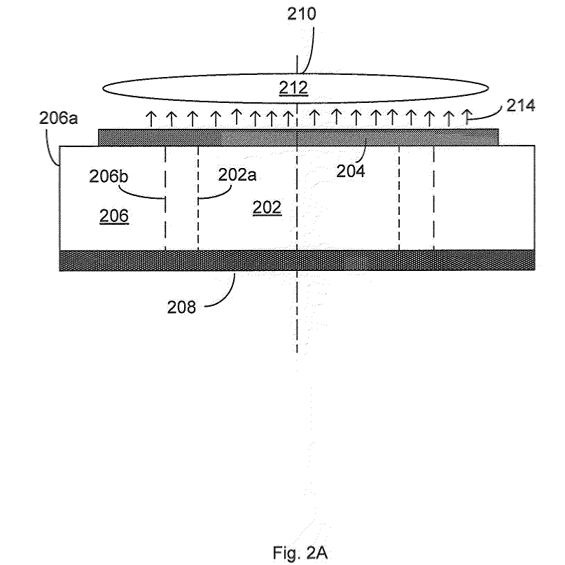

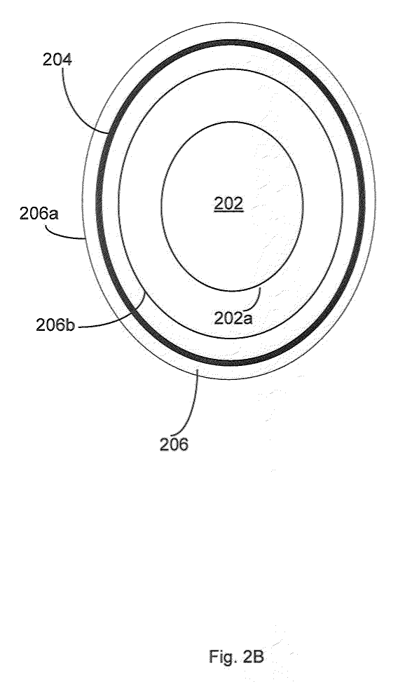

FIG. 2A is a cross sectional view of an exemplary microstrip antenna attached to a dielectric substrate outside a generally circular sputtering target. The sputtering target 202 (inside line 202a) has the center positioned along centerline 210. The dielectric substrate 206 between lines 206a and 206b surrounds the sputtering target 202 and is symmetric to the centerline 210. A microstrip antenna 204 is attached to a top of the dielectric substrate 206 between lines 206a and 206b. A ground plane 208 is attached to a bottom of the dielectric substrate 206. The microstrip antenna 204 radiates microwaves as pointed by arrow 214 into a cathode plasma sheath or dark space 212. The microwaves thus enhance plasma density near the cathode or sputtering target.

FIG. 2B is a top view of the microstrip antenna attached to a dielectric substrate outside the generally circular sputtering target shown in FIG. 2A. Note that the target 202 inside line 202a is generally circular in the center. The microstrip 204 is generally annular attached to the dielectric substrate that is also generally annular. The ground plane 208 (not shown) overlaps with the dielectric substrate 206 between lines 206a and 206b.

The microstrip antenna 204 may comprise a dielectric coated metal. The metal may comprise, among others, copper, aluminum, silver, or gold. The dielectric coating may comprise, but not limited to, Al₂O₃, SiO₂ etc. The microstrip antenna 204 may be attached to the dielectric substrate 206 by using an adhesive. Although FIGS. 2A and 2B show a space between the sputtering target 202 and the dielectric substrate 206, the dielectric substrate 206 may also contact the sputtering target 202 (not shown).

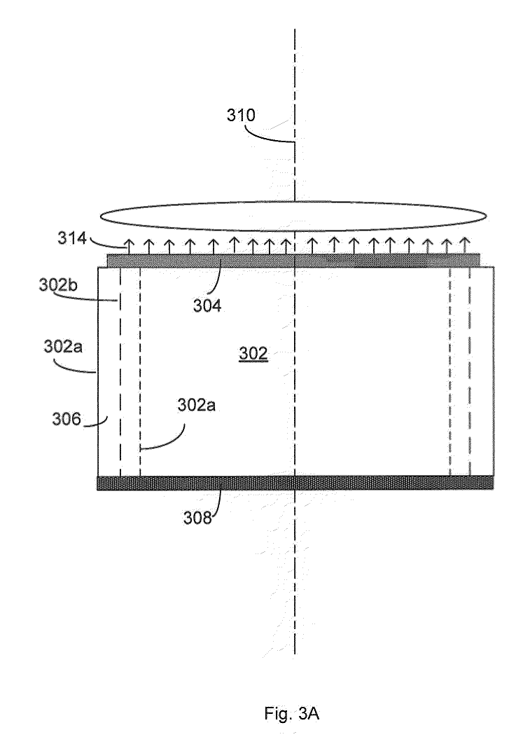

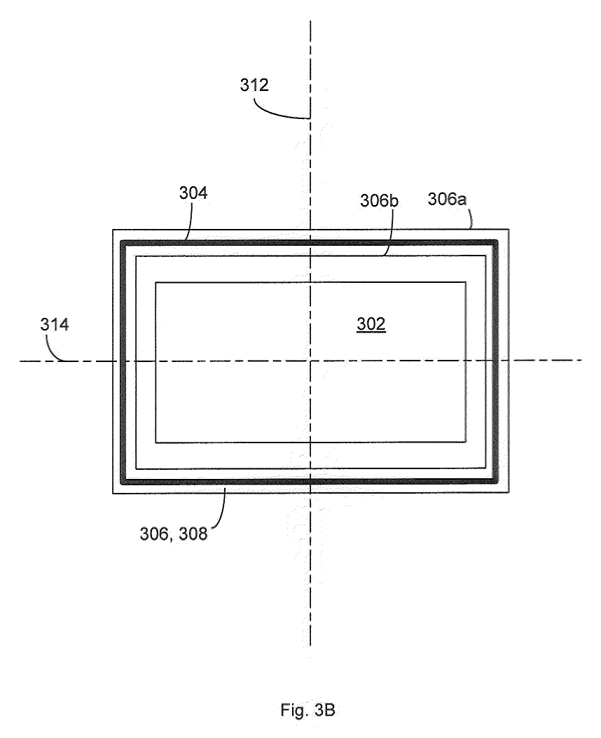

Referring to FIG. 3A now, it shows a cross sectional view of an exemplary microstrip antenna attached to a dielectric substrate outside a sputtering target of generally a rectangle. The sputtering target 302 within boundary line 302a is positioned in centerline 310. The dielectric substrate 306 between lines 302a and 302b surrounds the sputtering target 302 and is symmetric to centerline 310. A microstrip antenna 304 is attached to a top of the dielectric substrate 306. A ground plane 308 is attached to a bottom of the dielectric substrate 306. The microstrip antenna 304 radiates microwaves as pointed by arrow 316 into a cathode plasma sheath or dark space 312. The microwaves thus enhance plasma density near the cathode or sputtering target.

FIG. 3B is a top view of the microstrip antenna attached to a dielectric substrate outside the sputtering target of generally a rectangle shown in FIG. 3A. Note that the target 302 is of generally a rectangle positioned in centerlines 312 and 314. The microstrip 304 is of generally a strip shape attached to the dielectric substrate 306 between lines 306a and 306b. The dielectric substrate is of generally a strip shape and is symmetric to the centerlines 312 and 314. The ground plane 308 overlaps with the dielectric substrate 306 (not shown).

Those of ordinary skill in the art will realize that various configurations or geometries may be modified from the exemplary microstrips shown in FIGS. 2A-2B and 3A and 3B without departing from the spirit of the invention. Other variations will also be apparent to persons of skill in the art. These equivalents and alternatives are intended to be included within the scope of the present invention. Therefore, the scope of this invention should not be limited to the embodiments described. Various geometries or dimensions of microstrip antennas are also discussed in U.S. Patents, such as U.S. Pat. No. 4,185,252, U.S. Pat. Nos. 6,424,298, 6,424,298. Each of the foregoing patents is incorporated herein by reference for all purposes.

### 5. Exemplary Deposition Process

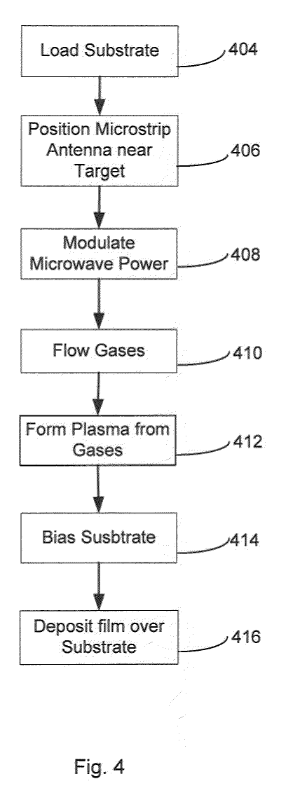

For purposes of illustration, FIG. 4 provides a flow diagram of a process that may be used to form a film on a substrate. First, a substrate is loaded into a processing chamber as indicated at block 404. A microstrip antenna that is attached to a dielectric layer is positioned near a sputtering target at block 406. The microwave power is modulated at block 408, for instance, by a power supply using a pulsing power or a continuous power. Film deposition is initiated by flowing gases, such as sputtering agents, at block 410.

The carrier gases may act as a sputtering agent. For example, the carrier gas may be provided with a flow of H₂ or with a flow of inert gas, including a flow of He or even a flow of a heavier inert gas such as Ar. The level of sputtering provided by the different carrier gases is inversely related to their atomic mass. Flow may sometimes be provided of multiple gases, such as by providing both a flow of H₂ and a flow of He, which mix in the processing chamber. Alternatively, multiple gases may sometimes be used to provide the carrier gases, such as when a flow of H₂/He is provided into the processing chamber.

As indicated at block 412, a plasma is formed from the gases by microwave at a frequency ranging from 1 GHz to 10 GHz, for example, commonly at 2.45 GHz (a wavelength of 12.24 cm). In addition, a higher frequency of 5.8 GHz is often used when power requirement is not as critical. The benefit of using a higher frequency source is that it has smaller size (about half size) of the lower frequency source of 2.45 GHz.

In some embodiments, the plasma may be a high-density plasma having an ion density that exceeds 10¹² ions/cm³. Also, in some instances the deposition characteristics may be affected by applying an electrical bias to the substrate at block 414. Application of such a bias causes the ionic species of the plasma to be attracted to the substrate, sometimes resulting in increased sputtering. The environment within the processing chamber may also be regulated in other ways in some embodiments, such as controlling the pressure within the processing chamber, controlling the flow rates of the gases and where they enter the processing chamber, controlling the power used in generating the plasma, controlling the power used in biasing the substrate and the like. Under the conditions defined for processing a particular substrate, material is thus deposited over the substrate as indicated at block 416.

### 6. Pulsing Microwave Power

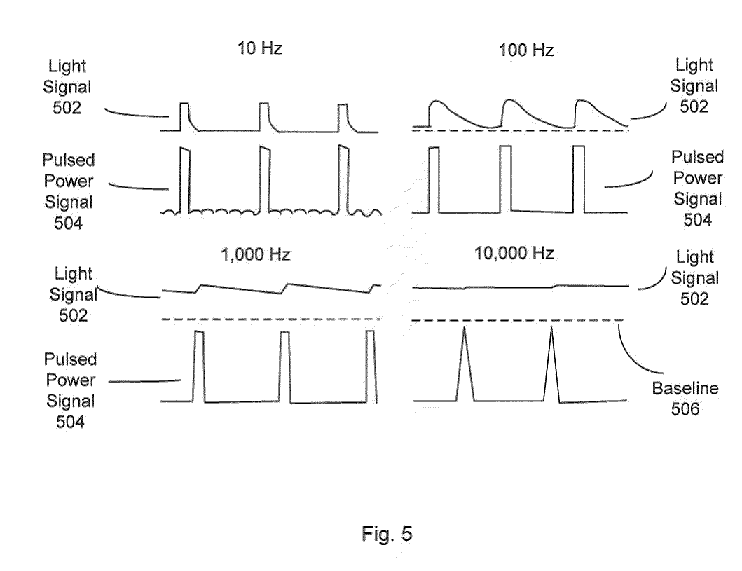

Pulsing frequency may affect the microwave pulsing power into plasma. FIG. 5 shows the frequency effect of the microwave pulsing power 504 on the light signal of plasma 502. The light signal of plasma 502 reflects the average radical concentration. As shown in FIG. 5, at a low pulsing frequency such as 10 Hz, in the event that all radicals are consumed, the light signal from plasma 502 decreases and extinguishes before the next power pulse comes in. As pulsing frequency increases to higher frequency such as 10,000 Hz, the average radical concentration is higher above the baseline 506 and becomes more stable.

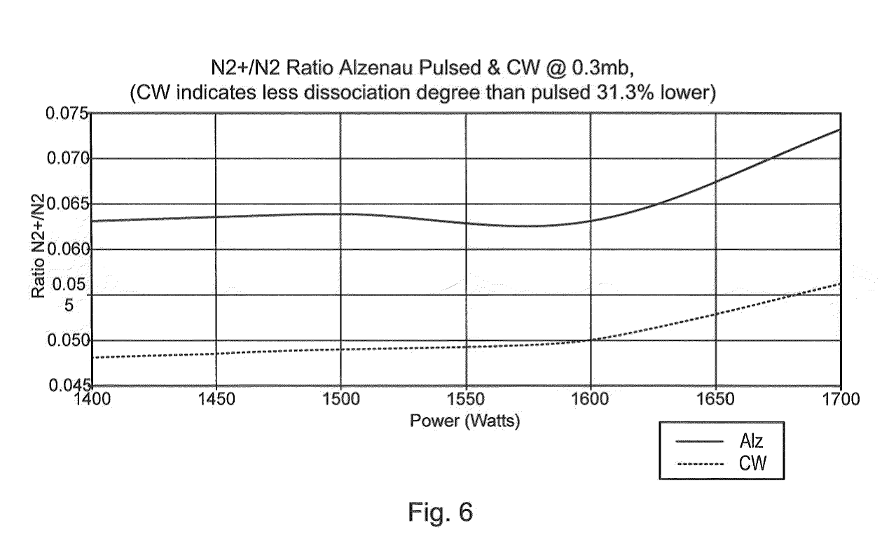

FIG. 6 shows the plasma density versus continuous microwave power. Note that when plasma density increases to above 2.2×10¹¹/cm³, the plasma density starts to saturate with increasing microwave power. The reason for this saturation is that the microwave radiation is reflected more once the plasma density becomes dense. Due to the limited power in available microwave sources, microwave plasma linear sources of any substantial length may not achieve optimal plasma conditions, i.e. very dense plasma. Pulsing microwave power allows for much higher peak energy into the antenna than continuous microwaves, such that the optimal plasma condition can be approached.

FIG. 7 shows a graph which illustrates the improved plasma efficiency of pulsing microwaves over continuous microwaves, assuming that the pulsing microwaves have the same average power as the continuous microwaves. Note that continuous microwaves result in less disassociation as measured by the ratio of nitrogen radical N₂+ over neutral N₂. A 31% increase in plasma efficiency can be achieved by using pulsing microwave power.

While the above is a complete description of specific embodiments of the present invention, various modifications, variations and alternatives may be employed. Moreover, other techniques for varying the parameters of deposition could be employed in conjunction with the microstrip antennas. Examples of the possible variations include but are not limited to different geometries of the microstrip antennas or sputtering targets, variations in dimensions and configurations of the microstrip antennas, different waveforms for pulsing power applied to the microstrip antennas, DC, RF or pulsing power to the target, the RF bias condition for the substrate, the temperature of the substrate, the pressure of deposition, and the flow rate of inert gases and the like.

Having described several embodiments, it will be recognized by those skilled in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

What is claimed is:

1. A system for microwave assisted sputtering deposition, comprising:
a processing chamber;
a sputtering target or cathode positioned inside the processing chamber;
a gas supply system for providing sputtering agents into the processing chamber, wherein a plasma is formed from the sputtering agents;
a microstrip antenna attached to an end of a dielectric layer positioned outside the sputtering target; and
a substrate supporting member disposed within the processing chamber and configured to support a substrate.

2. The system for microwave assisted sputtering deposition of claim 1, wherein microwaves generated from the microstrip antenna are radiated into a space between the sputtering target and a cathode dark space for enhancing plasma density, the cathode dark space being proximate the target.

3. The system for microwave assisted sputtering deposition of claim 1, wherein the target comprises a metal or a dielectric material.

4. The system for microwave assisted sputtering deposition of claim 1, wherein the target has a generally circular cross section.

5. The system for microwave assisted sputtering deposition of claim 4, wherein the microstrip antenna comprises a ring strip.

6. The system for microwave assisted sputtering deposition of claim 1, wherein the target has a generally rectangular cross section.

7. The system for microwave assisted sputtering deposition of claim 6, wherein the microstrip antenna comprises a substantially rectangular cross section.

8. The system for microwave assisted sputtering deposition of claim 1, wherein the microstrip antenna comprises a dielectric coated metal.

9. The system for microwave assisted sputtering deposition of claim 1, wherein a power source is adapted to the target for providing a DC power, an AC power, an RF power, or a pulsed power.

10. A method for depositing a film on a substrate, the method comprising:
loading a substrate into a processing chamber by disposing the substrate over a substrate supporting member;
attaching a microstrip antenna to a dielectric layer outside a sputtering target that is disposed within the processing chamber;
generating microwaves with the microstrip antenna;
modulating a power of the generated microwaves;
flowing gases into the processing chamber;
generating a plasma inside the processing chamber with a power source adapted to apply a voltage to the target, a density of the plasma being further enhanced with the generated microwaves; and
forming a layer on the substrate with the plasma.

11. A method for depositing a film on a substrate of claim 10, wherein the power source comprises a DC power, or an AC power, an RF power or a pulsed power.

12. A method for depositing a film on a substrate of claim 10, wherein the target comprises a metal, dielectric material, or a semiconductor.

13. A method for depositing a film on a substrate of claim 10, wherein the microstrip antenna is constructed from a dielectric coated metal.

14. A method for depositing a film on a substrate of claim 10, wherein the microstrip antenna comprises a shape of generally a curved strip or a straight strip.

15. A method for depositing a film on a substrate of claim 10, wherein the microwave power is modulated by a pulsing or continuous power supply.
